(19) United States
(12) Patent Application Publication
(10) Pub. No.: US 2005/0194698 A1
(43) Pub. Date: Sep. 8, 2005

(54) Integrated circuit package with keep-out zone overlapping undercut zone

(75) Inventors: Il Kwon Shim, Singapore (SG); Virgil Cotoco Ararao, Singapore (SG); Hyeong Ryeol Hur, Singapore (SG); Byung Joon Han, Singapore (SG)

Correspondence Address: THE LAW OFFICES OF MIKIO ISHIMARU, 1110 SUNNYVALE-SARATOGA ROAD, SUITE A1, SUNNYVALE, CA, 94087, US

(73) Assignee: ST Assembly Test Service Ltd., Singapore (SG)

(21) Appl. No.: 10/794,109

(22) Filed: Mar. 3, 2004

(51) Int. Cl. H01L 23/48

(52) U.S. Cl. 257/784

(57) ABSTRACT

An integrated circuit package is provided with a connective structure having a wire bonding zone and a keep-out zone. An integrated circuit die has an undercut defining an undercut zone, which is overlapped by the keep-out zone. A wire is bonded between the integrated circuit die and the connective structure within the wire bonding zone and outside of the keep-out zone.

### TECHNICAL FIELD

The present invention relates generally to semiconductor packages, and more particularly to single or side-by-side multichip packages.

### BACKGROUND ART

In the electronics industry, as products such as cell phones and cameras become smaller and smaller, increased miniaturization of integrated circuit packages has become more and more critical. At the same time, higher performance and lower cost have become essential for new products. Semiconductor devices are constructed from a silicon (Si) or gallium-arsenide (Ga/Ar) wafer through a process that comprises a number of deposition, masking, diffusion, etching, and implanting steps. Usually, many individual devices are constructed on the same wafer. When the devices are separated into individual groups of units, each takes the form of an integrated circuit die.

In order to interface an integrated circuit die with other circuitry, it is common to mount it on a leadframe or on a multichip module substrate that is surrounded by a number of lead fingers. Each die has bonding pads that are then individually connected in a wire bonding operation to the lead fingers of the leadframe using extremely fine gold (Au) or aluminum (Al) wires. The assemblies are then packaged by individually encapsulating them in molded plastic, epoxy, or ceramic bodies.

One approach to putting more integrated circuit dies in a single package involves stacking the dies with space between the dies for wire bonding. The space is achieved by means of a thick layer of organic adhesive or in combination with inorganic spacers of material such as silicon, ceramic, or metal. Unfortunately, the stacking adversely affects the performance of the package because of decreased thermal performance due to the inability to remove heat through the organic adhesive and/or inorganic spacers. As the stacking of the dies increases, thermal resistance increases at a faster rate. Further, such stacked dies have a high manufacturing cost.

Each attempt to reduce the size of the integrated circuit package tends to create additional problems with cost, heat transfer, and electrical performance.

Solutions to these problems have been long sought, but prior developments have not taught or suggested any solutions and, thus, solutions to these problems have long eluded those skilled in the art.

### DISCLOSURE OF THE INVENTION

The present invention provides an integrated circuit package with a connective structure having a wire bonding zone and a keep-out zone. An integrated circuit die has an undercut defining an undercut zone, which is overlapped by the keep-out zone. A wire is bonded between the integrated circuit die and the connective structure within the wire bonding zone and outside of the keep-out zone.

This reduces the size of the integrated circuit package and minimizes problems such as high fabrication cost, poor heat transfer, and decreased electrical performance.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a close-up cross-sectional view of one edge of a base integrated circuit package in accordance with the present invention;

FIG. 2 is a close-up cross-sectional view of one edge of a ball grid array integrated circuit package in accordance with the present invention;

FIG. 3 is a close-up cross-sectional view of one edge of a leaded integrated circuit package in accordance with the present invention;

FIG. 4 is a close-up cross-sectional view of one edge of a leaded integrated circuit package in accordance with the present invention;

FIG. 5 is a close-up cross-sectional view of one edge of another leaded integrated circuit package in accordance with the present invention;

FIG. 6 is a close-up cross-sectional view of one edge of a leadless integrated circuit package in accordance with the present invention;

FIG. 7 is a close-up cross-sectional view of one edge of another embodiment of a leadless integrated circuit package in accordance with the present invention;

FIG. 8 is a close-up cross-sectional view of one edge of a land grid array integrated circuit package in accordance with the present invention:

FIG. 9 is a close-up cross-sectional view of one edge of a leaded integrated circuit package in accordance with the present invention; and

FIG. 10 is a close-up cross-sectional view of one edge of another leaded integrated circuit package in accordance with the present invention.

### BEST MODE FOR CARRYING OUT THE INVENTION

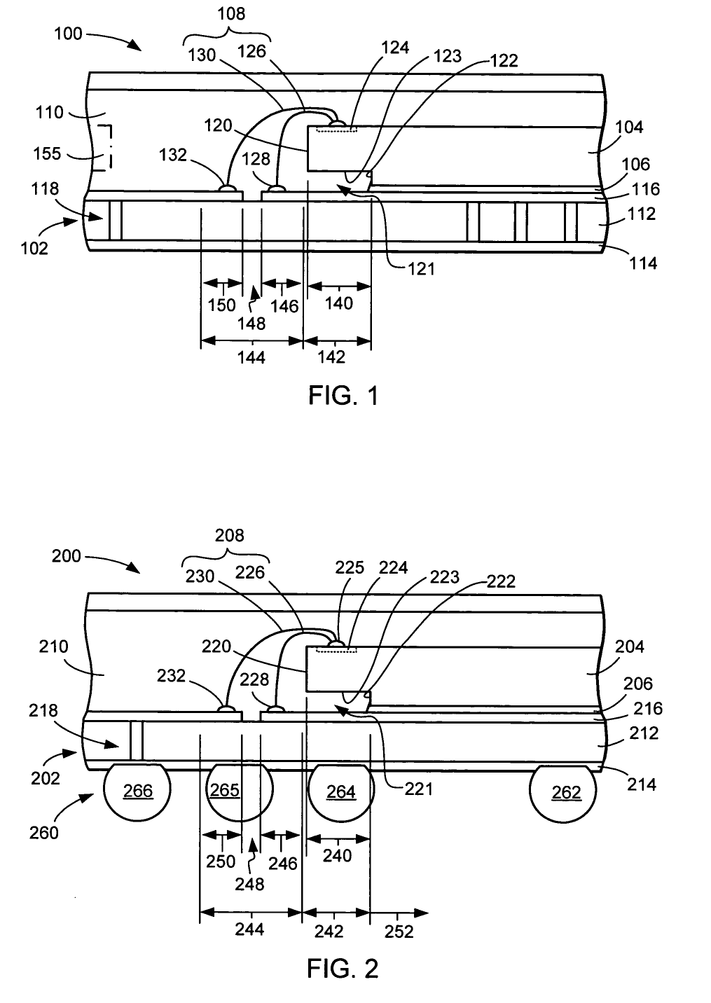

Referring now to FIG. 1, therein is shown a close-up cross-sectional view of an integrated circuit package 100 in accordance with the present invention. The basic integrated circuit package 100 includes a package substrate 102, an integrated circuit die 104, bonding adhesive 106, bonding wires 108, and an encapsulant 110.

In the following description, numerous specific details are given to provide a thorough understanding of the invention. However, it will apparent that the invention may be practiced without these specific details. In order to avoid obscuring the present invention, some well-known system configurations and process steps are not disclosed in detail.

The term “horizontal” as used herein is defined as a plane parallel to the conventional plane or surface of the integrated circuit die, regardless of its orientation. The term “vertical” refers to a direction perpendicular to the horizontal as just defined. Terms, such as “on”, “above”, “below”, “bottom”, “top”, “over”, and “under”, are defined with respect to the horizontal plane.

Likewise, the drawings showing embodiments of the invention are semi-diagrammatic and not to scale and, particularly, some of the dimensions are for the clarity of presentation and are shown greatly exaggerated in the FIGs. In addition, since multiple embodiments are disclosed and described having some features in common, for clarity and ease of illustration and description thereof like features one to another will sometimes be described with like reference numerals.

The package substrate 102 is a connective structure, which includes an insulator 112, such as plastic or ceramic. The insulator 112 has bottom and top patterned metal layers 114 and 116, respectively, connected by through vias 118. The patterned metal layers 114 and 116 and the through vias 118 can be made of conductive metals such as copper (Cu) and aluminum (Al).

The term “connective structure” defines a structure that connects the connections from integrated circuit die to the connections for a printed circuit board or other external structure.

The integrated circuit die 104 has an outside edge 120 and an undercut 121 with an inside edge 122, which is a first width from the outside edge 120. The undercut 121 has a top side 123, which is a first height from the bottom of the integrated circuit die 104. The undercut 121 extends along at least one side of the integrated circuit die 104 and is on the back or bottom side opposite the side containing a number of contact pads 124.

The bonding adhesive 106 can be a thermally and/or electrically conductive or non-conductive adhesive or epoxy.

The bonding wires 108 can be ground wires 126 connected by wire bonds 125 to the contact pads 124 and to ground wire bonds 128, or signal wires 130 connected by the wire bonds 125 to other of the contact pads 124 and to signal wire bonds 132.

The encapsulant 110 can be an epoxy or plastic, which covers the top of the package substrate 102 and encapsulates the integrated circuit die 104, the bonding adhesive 106, and the bonding wires 108.

In the present invention, the overhang of the undercut 121 defines an undercut zone 140 under the integrated circuit die 104 that is the same distance as the width from the outside edge 120 to the inside edge 122. The distance from the inside edge 122 to the ground wire bonds 128 is designated as a “keep-out zone”, which in this embodiment is a wire bonding keep-out zone 142. The wire bonding keep-out zone 142 is a region around the integrated circuit die 104 in which wire bonds cannot be made. This is generally because of epoxy used to attach the integrated circuit die 104 to the substrate 102. Epoxy spread and epoxy resin bleed can result in wire bonds not being made or failing after a short period of time or other wire bond problems. There are a number of other factors, which affect the size of the wire bonding keep-out zone 142 depending on the package such as the capability of the wire bonding equipment to form bonds close to the integrated circuit die.

The wire bonding keep-out zone 142 is adjacent to a wire bonding zone 144, which is a region of possible locations for the bonding wires 108. In the integrated circuit package 100, the wire bonding zone 144 is divided up into a ground wire bonding zone 146 for the ground wire bonds 128 spaced by a separation zone 148 from a signal wire bonding zone 150 for the signal wire bonds 132.

In the past, the wire bonding keep-out zone 142 would have been a specified distance from the outside edge 120 of the integrated circuit die 104. However, in the present invention the distance of the wire bonding keep-out zone 142 is measured from the inside edge 122.

In the embodiment shown, the wire bonding keep-out zone 142 overlaps and is only slightly wider than the undercut zone 140. Since the wire bonding keep-out zone 142 is closer to the integrated circuit die 104 than previously possible because of the undercut zone 140, both the ground wire bonding zone 146 and the signal wire bonding zone 150 may also be closer to the integrated circuit die 104.

The above means that side-by-side dies can be placed closer together than in conventional integrated circuit packages without reducing integrated circuit die size. Conversely, the integrated circuit die size may be increased while maintaining the same wire bonding keep-out zone 142. At the same time, the present invention will provide shorter bonding wire lengths and higher grounding wire densities, which result in improved electrical performance over conventional integrated circuit packages.

Referring now to FIG. 2, therein is shown a close-up cross-sectional view of a ball grid array (BGA) integrated circuit package 200 in accordance with the present invention. The BGA integrated circuit package 200 includes a package substrate 202, an integrated circuit die 204, bonding adhesive 206, bonding wires 208, and an encapsulant 210.

The package substrate 202 is a connective structure, which includes an insulator 212, such as plastic or ceramic. The insulator 212 has bottom and top patterned metal layers 214 and 216 connected by through vias 218. The patterned metal layers 214 and 216 and the through vias 218 can be made of conductive metals such as copper (Cu) and aluminum (Al).

The integrated circuit die 204 has an outside edge 220 and an undercut 221 with an inside edge 222, which is a first width from the outside edge 220. The undercut 221 has a top side 223, which is a first height from the bottom of the integrated circuit die 204. The undercut 221 extends along at least one side of the integrated circuit die 204 and is on the back or bottom side opposite the side containing a number of contact pads 224.

The bonding adhesive 206 can be a thermally and/or electrically conductive or non-conductive adhesive or epoxy.

The bonding wires 208 can be ground wires 226 connected by wire bonds 225 to the contact pads 224 and to ground wire bonds 228, or signal wires 230 connected by the wire bonds 225 to other of the contact pads 224 and to signal wire bonds 232.

The encapsulant 210 can be a epoxy or plastic, which covers the package substrate 202 and encapsulates the integrated circuit die 204, the bonding adhesive 206, and the bonding wires 208.

In the present invention, the overhang of the undercut 221 defines an undercut zone 240 under the integrated circuit die 204 that is the same distance as the distance from the outside edge 220 to the inside edge 222. The distance from the inside edge 222 to the ground wire bonds 228 is designated as a “keep-out zone”, which in this embodiment is a wire bonding keep-out zone 242. The wire bonding keep-out zone 242 is adjacent to a wire bonding zone 244, which is divided up into a ground wire bonding zone 246 for the ground wire bonds 228 spaced by a separation zone 248 from a signal wire bonding zone 250 for the signal wire bonds 232.

In the embodiment shown, the wire bonding keep-out zone 242 overlaps and is only slightly wider than the undercut zone 240. Since the wire bonding keep-out zone 242 is closer to the integrated circuit die 204 than previously possible because of the undercut zone 240, both the ground wire bonding zone 244 and the signal wire bonding zone 248 may also be closer to the integrated circuit die 204. This permits placing side-by-side dies closer together than in conventional integrated circuit packages without reducing integrated circuit die size. Conversely, the integrated circuit die size may be increased while maintaining the same wire bonding keep-out zone. At the same time, the present invention will provide shorter wire lengths and higher grounding densities, which result in improved electrical performance over conventional integrated circuit packages.

The underside of the package substrate 202 is provided with solder balls 260 which include solder balls for thermal or ground terminals 262 and signal terminals 264 through 266. The thermal or ground terminals 262 are located under a die bonding zone 252 where the integrated circuit die 204 is bonded to the top patterned metal layer 216.

Previously, some of the signal terminals would be at least partially under an outside edge of the integrated circuit die, but in the present invention, the signal terminals 264 through 266 may be at least partially under the undercut zone 240 but are outside the inside edge 222 of the integrated circuit die 204; i.e., are not under the die bonding zone 252. The thermal or ground terminals 262 are within the inside edge 222 of the integrated circuit die 204.

It has been discovered that having the solder balls 260 of the signal terminals 264 through 266 outside the die bonding zone 252 results in better solder joint reliability and fatigue life of the solder balls 260. In most cases, solder ball (e.g., the solder ball 264) along or within the die edge area has a lower life span, this is due to unbalanced stress due to thermal expansion within this region. One side has no support/counter force at all and the other has the bonding adhesive 206.

For thermal/ground terminals, the strain induced this region is less due to the presence of bonding adhesive 206 and integrated circuit die 204, this will serve as a counter force, therefore the strain induced to the solder ball underneath is less. However, there are a number of other factors such as design, materials, and processes, which were found to influence solder joint reliability and fatigue life.

The integrated circuit packages 100 and 200 are array package applications. The integrated circuit package 100 has superior electrical performance and routing density in addition to better solder joint reliability compared to comparable prior integrated circuit packages. The integrated circuit package 200 has better electrical performance and routing density, but superior solder joint reliability compared to comparable prior integrated circuit packages.

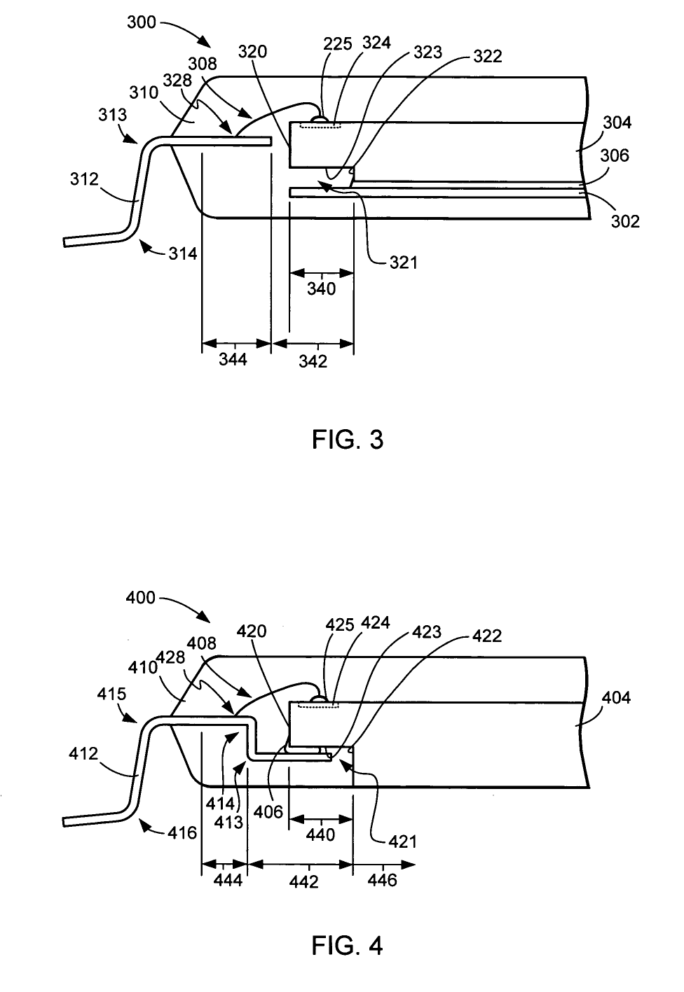

Referring now to FIG. 3, therein is shown a close-up cross-sectional view of a leaded integrated circuit package 300. The leaded integrated circuit package 300 includes a package substrate 302, an integrated circuit die 304, bonding adhesive 306, bonding wires 308, an encapsulant 310, and lead fingers 312.

The package substrate 302 is a die paddle of a conductive material such as copper or aluminum.

The integrated circuit die 304 has an outside edge 320 and an undercut 321 with an inside edge 322, which is a first width from the outside edge 320. The undercut 321 has a top side 323, which is a first height from the bottom of the integrated circuit die 304. The undercut 321 extends along at least one side of the integrated circuit die 304 and is on the back or bottom side opposite the side containing a number of contact pads 324.

The bonding adhesive 306 can be a thermally and/or electrically conductive or non-conductive adhesive or epoxy.

The lead fingers 312 are connective structures, which are not connected to but extend outward from the integrated circuit die 304 and bend downward at a first bend 313. After extending below the integrated circuit die 304, the lead fingers 312 bend outward at a second bend 314. Die paddle 302 can be directly connected to at least one lead finger 312 through tie bar (not shown) as a special lead finger for thermal dissipation or ground finger.

The bonding wires 308 can be ground and signal wires connected by wire bonds 325 to the contact pads 324 and to wire bonds 328 on the lead fingers 312 between the inner ends of the lead fingers 312 and the first bends 313. The ground wires are optional but are generally placed on the corners of the integrated circuit die 304 to connect to the corner lead fingers 312.

The encapsulant 310 encapsulates the package substrate 302, the integrated circuit die 304, the bonding adhesive 306, the bonding wires 308, and a portion of the lead fingers 312.

In the present invention, the undercut 321 defines an undercut zone 340 under the integrated circuit die 304 that is the same distance as the distance from the outside edge 320 to the inside edge 322. The distance from the inside edge 322 to the inner lead finger tip 312 is designated as a “keep-out zone”, which in this embodiment is a die-to-finger keep-out zone 342 (generically the “keep-out zone”). The die-to-finger keep-out zone 342 is adjacent to a wire bonding zone 344.

In the embodiment shown, the die-to-finger keep-out zone 342 is closer to the integrated circuit die 304 than previously possible because of the undercut zone 340, the wire bonding zone 344 may also be closer to the integrated circuit die 304. This permits increasing the integrated circuit die size while maintaining the same wire bonding keep-out zone or substantially decreasing the package size. At the same time, the present invention will provide shorter wire lengths and higher grounding densities, which result in improved electrical performance over conventional integrated circuit packages.

Referring now to FIG. 4, therein is shown a close-up cross-sectional view of a leaded integrated circuit package 400. The leaded integrated circuit package 400 includes an integrated circuit die 404, bonding adhesive 406, bonding wires 408, an encapsulant 410, and lead fingers 412.

The integrated circuit die 404 has an outside edge 420 and an undercut 421 with an inside edge 422, which is a first width from the outside edge 420. The undercut 421 has a top side 423, which is a first height from the bottom of the integrated circuit die 404. The undercut 421 extends along at least one side of the integrated circuit die 404 and is on the back or bottom side opposite the side containing a number of contact pads 424.

The bonding adhesive 406 can be a thermally and/or electrically conductive or non-conductive adhesive or epoxy. In this embodiment, the bonding adhesive 406, when a conductive adhesive or epoxy, can conduct heat away from the integrated circuit die 404 through the lead fingers 412 in addition to through the exposed bottom of the integrated circuit die 404.

The lead fingers 412 are connective structures that are bonded to integrated circuit die 404 to the top side 423 of the undercut 421 with the bonding adhesive 406 on top of the lead fingers 412. The lead fingers 412 extend outward to first bends 413 where the lead fingers 412 bend upward. At second bends 414, the lead fingers 412 bend outward and extend to third bends 415. The third bends 415 bend the lead fingers 412 downward to fourth bends 416 from where the lead fingers 412 bend outward.

The bonding wires 408 can be ground and signal wires connected by wire bonds 425 to the contact pads 424 and to wire bonds 428 on the top surface of the lead fingers 412 between the second and third bends 414 and 415.

The encapsulant 410 encapsulates the integrated circuit die 404, the bonding adhesive 406, and the bonding wires 408. The encapsulant 410 also encapsulates the lead fingers 412 almost up to the third bends 415. In the embodiment shown, the encapsulant 410 does not cover the back or bottom of the integrated circuit die 404 so that thermal performance can be further improved by allowing air convention or an external heat spreader to access to an underside area 446.

In the present invention, the undercut 421 defines an undercut zone 440 under the integrated circuit die 404 that is the same distance as the distance from the outside edge 420 to the inside edge 422. The distance from the inside edge 422 to the wire bond 428 is designated as a “keep-out zone”, which in this embodiment is a wire bonding keep-out zone 442. The wire bonding keep-out zone 442 is adjacent to a wire bonding zone 444.

In the embodiment shown, the wire bonding keep-out zone 442 considerably overlaps and is much wider than the undercut zone 240. However, since the wire bonding keep-out zone 442 is closer to the integrated circuit die 404 than previously possible because of the undercut zone 440, the wire bonding zone 444 may also be closer to the integrated circuit die 404. This permits increasing the integrated circuit die size while maintaining the same wire bonding keep-out zone or substantially decreasing the package size. At the same time, the present invention will provide shorter wire lengths and higher grounding densities, which result in improved electrical performance over conventional integrated circuit packages.

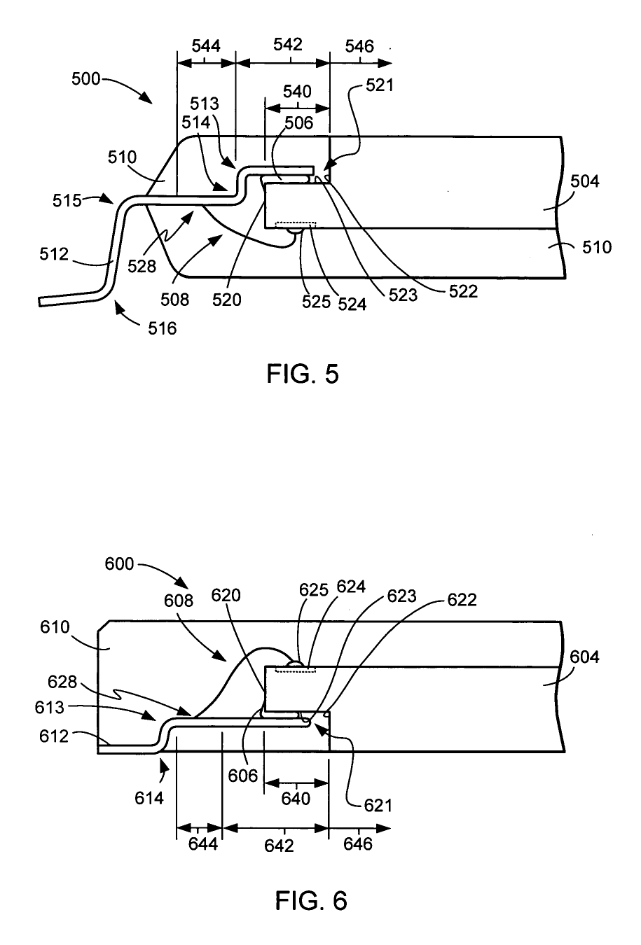

Referring now to FIG. 5, therein is shown a close-up cross-sectional view of a leaded integrated circuit package 500. The leaded integrated circuit package 500 includes an integrated circuit die 504, bonding adhesive 506, bonding wires 508, an encapsulant 510 and lead fingers 512.

The integrated circuit die 504 has an outside edge 520 and an undercut 521 with an inside edge 522, which is a first width from the outside edge 520. The undercut 521 has a top side 523, which is a first height from the bottom of the integrated circuit die 504. The undercut 521 extends along at least one side of the integrated circuit die 504 and is on the back or bottom side opposite the side containing a number of contact pads 524.

The bonding adhesive 506 can be a thermally and/or electrically conductive or non-conductive adhesive or epoxy. In this embodiment, the bonding adhesive 506, when a thermally conductive adhesive or epoxy, can conduct heat away from the integrated circuit die 504 through the lead fingers 512.

The lead fingers 512 are connective structures that are bonded to a flipped over integrated circuit die 504 to the top side 523 of the undercut 521 with the bonding adhesive 506 on top of the lead fingers 512. The lead fingers 412 extend outward to first bends 515 where the lead fingers 512 bend upward. At second bends 516, the lead fingers 512 bend outward and extend to third bends 517. The third bends 517 bend the lead fingers 512 upward to fourth bends 518 from where the lead fingers 512 bend outward.

The bonding wires 508 can be ground and signal wires connected to the contact pads 524 and to wire bonds 528 on the top surface of the lead fingers 512 between the second and third bends 516 and 517.

The encapsulant 510 encapsulates the integrated circuit die 504, the bonding adhesive 506, and the bonding wires 508. The encapsulant 510 also encapsulates the lead fingers 512 almost up to the third bends 516. In this embodiment, the encapsulant 510 does not cover the back or bottom of the integrated circuit die 504 so that thermal performance can be further improved by allowing air convection or an external heat spreader to access to a topside area 546.

In the present invention, the undercut 521 defines an undercut zone 540 under the integrated circuit die 504 that is the same distance as the distance from the outside edge 520 to the inside edge 522. The distance from the inside edge 522 to the wire bond 528 is designated as a “keep-out zone”, which in this embodiment is a wire bonding keep-out zone 542. The wire bonding keep-out zone 542 is adjacent to a wire bonding zone 544.

In the present invention, the wire bonding keep-out zone 542 overlaps and is wider than the undercut zone 540. Since the wire bonding keep-out zone 542 is closer to the integrated circuit die 504 than previously possible because of the undercut zone 540, the wire bonding zone 544 may also be closer to the integrated circuit die 504. This permits increasing the integrated circuit die size while maintaining the same wire bonding keep-out zone or keeping the integrated circuit die size the same and decreasing the package size. At the same time, the present invention will provide shorter wire lengths and higher grounding densities, which result in improved electrical performance over convectional integrated circuit packages.

Referring now to FIG. 6, therein is shown a close-up cross-sectional view of a leadless integrated circuit package 600. The leaded integrated circuit package 600 includes an integrated circuit die 604, bonding adhesive 606, bonding wires 608, an encapsulant 610, and lead fingers 612.

The integrated circuit die 604 has an outside edge 620 and an undercut 621 with an inside edge 622, which is a first width from the outside edge 620. The undercut 621 has a top side 623, which is a first height from the bottom of the integrated circuit die 604. The undercut 621 extends along at least one side of the integrated circuit die 604 and is on the back or bottom side opposite the side containing a number of contact pads 624.

The bonding adhesive 606 can be a thermally and/or electrically conductive or non-conductive adhesive or epoxy. In this embodiment, the bonding adhesive 606, when a thermally conductive adhesive or epoxy, can conduct heat away from the integrated circuit die 604 through the lead fingers 612.

The lead fingers 612 are connective structures that are bonded to the integrated circuit die 604 to the top side 623 of the undercut 621 with the bonding adhesive 606 on top of the lead fingers 612. The lead fingers 612 extend outward to first bends 613 where the lead fingers 612 bend downward. At second bends 614, the lead fingers 612 bend outward to form a leadless configuration for the leadless integrated circuit package 600.

The bonding wires 608 can be ground and signal wires connected to the contact pads 624 and to wire bonds 628 on the top surface of the lead fingers 612 before the first bends 613.

The encapsulant 610 encapsulates the integrated circuit die 604, the bonding adhesive 606, and the bonding wires 608. The encapsulant 610 also encapsulates the lead fingers 612 and only exposes a bottom portion of the lead fingers 612 after the second bends 614. In this embodiment, the encapsulant 610 does not cover the back or bottom of the integrated circuit die 604 so that thermal performance can be further improved by allowing air convection or an external heat spreader to access to an underside area 646.

In the present invention, the undercut 621 defines an undercut zone 640 under the integrated circuit die 604 that is the same distance as the distance from the outside edge 620 to the inside edge 622. The distance from the inside edge 622 to the wire bond 628 is designated as a “keep-out zone”, which in this embodiment is a wire bonding keep-out zone 642. The wire bonding keep-out zone 642 is adjacent to a wire bonding zone 644.

In the present invention, the wire bonding keep-out zone 642 overlaps and is significantly wider than the undercut zone 640. Since the wire bonding keep-out zone 642 is closer to the integrated circuit die 604 than previously possible because of the undercut zone 640, the wire bonding zone 644 may also be closer to the integrated circuit die 604. This permits increasing the integrated circuit die size while maintaining the same wire bonding keep-out zone or keeping the integrated circuit die size the same and decreasing the package size. At the same time, the present invention will provide shorter wire lengths and higher grounding densities, which result in improved electrical performance over convectional integrated circuit packages.

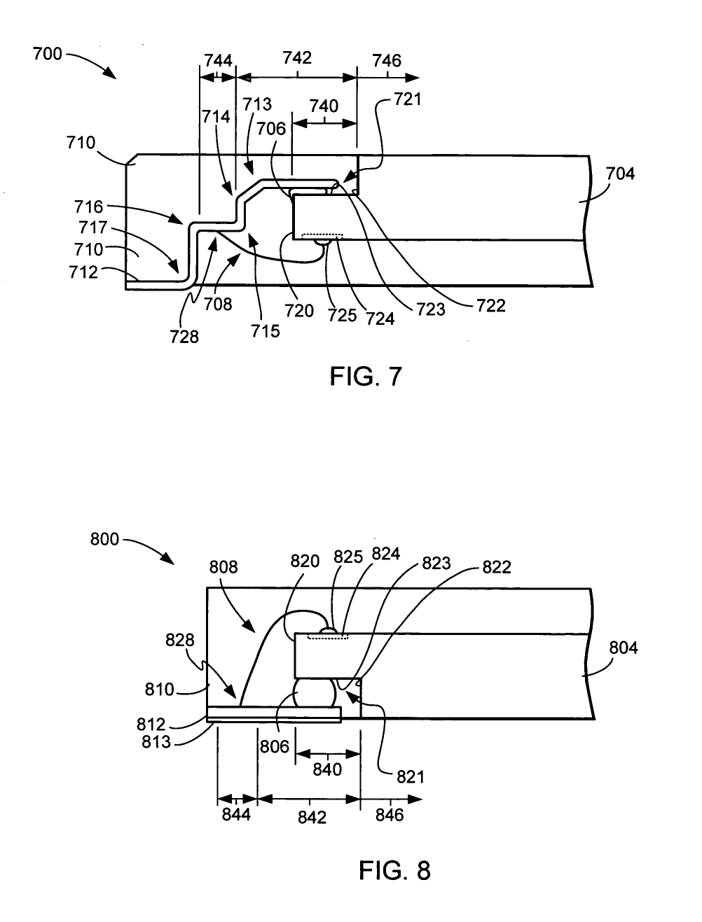

Referring now to FIG. 7, therein is shown a close-up cross-sectional view of a leadless integrated circuit package 700. The leaded integrated circuit package 700 includes an integrated circuit die 704, bonding adhesive 706, bonding wires 708, an encapsulant 710, and lead fingers 712.

The integrated circuit die 704 has an outside edge 720 and an undercut 721 with an inside edge 722, which is a first width from the outside edge 720. The undercut 721 has a top side 723, which is a first height from the bottom of the integrated circuit die 704. The undercut 721 extends along at least one side of the integrated circuit die 704 and is on the back or bottom side opposite the side containing a number of contact pads 724.

The bonding adhesive 706 can be a thermally and/or electrically conductive or non-conductive adhesive or epoxy. In this embodiment, the bonding adhesive 706, when a conductive adhesive or epoxy, can conduct heat away from the integrated circuit die 704 through the lead fingers 712.

The lead fingers 712 are connective structures that are bonded to the flipped integrated circuit die 704 to the top side 723 of the undercut 721 with the bonding adhesive 706 on top of the lead fingers 712. The lead fingers 712 extend outward to first bends 713 where the lead fingers 712 bend 450 downward. At second bends 714, the lead fingers 712 bend downward 45° and extend to third bends 715. At third bends 715, the lead fingers 712 bend outward to fourth bends 716 from where the lead fingers 712 bend downward to fifth bends 717 where the lead fingers 712 bend outward again to form the leadless portion of the leadless integrated circuit package 700.

The bonding wires 708 can be ground and signal wires connected to the contact pads 724 and to wire bonds 728 on the top surface of the lead fingers 712 between the third and fourth bends 715 and 716.

The encapsulant 710 encapsulates the integrated circuit die 704, the bonding adhesive 706, and the bonding wires 708. The encapsulant 710 also encapsulates the lead fingers 712 and only exposes a bottom portion of the lead fingers 712 after the fifth bends 717. In this embodiment, the encapsulant 710 does not cover the back or bottom of the integrated circuit die 704 so that thermal performance can be further improved by allowing air convection or an external heat spreader to access to a topside area 746.

In the present invention, the undercut 721 defines an undercut zone 740 under the integrated circuit die 704 that is the same distance as the distance from the outside edge 720 to the inside edge 722. The distance from the inside edge 722 to the wire bond 728 is designated as a “keep-out zone”, which in this embodiment is a wire bonding keep-out zone 742. The wire bonding keep-out zone 742 is adjacent to a wire bonding zone 744.

In the present invention, the wire bonding keep-out zone 742 overlaps and is significantly wider than the undercut zone 740. Since the wire bonding keep-out zone 742 is closer to the integrated circuit die 704 than previously possible because of the undercut zone 740, the wire bonding zone 744 may also be closer to the integrated circuit die 704. This permits increasing the integrated circuit die size while maintaining the same wire bonding keep-out zone or maintaining the integrated circuit die size while decreasing the size of the integrated circuit package. At the same time, the present invention will provide shorter wire lengths and higher grounding densities, which result in improved electrical performance over convectional integrated circuit packages.

Referring now to FIG. 8, therein is shown a close-up cross-sectional view of a land grid array (LGA) integrated circuit package 800 in accordance with the present invention. The land grid array integrated circuit package 800 includes a laminate substrate 802, an integrated circuit die 804, bonding adhesive 806, bonding wires 808, and an encapsulant 810.

The laminate substrate 802 is a connective structure that has an array of metal pads 813 that receive corresponding solder traces on a printed circuit board (not shown).

The integrated circuit die 804 has an outside edge 820 and an undercut 821 with an inside edge 822, which is a first width from the outside edge 820. The undercut 821 has a top side 823, which is a first height from the bottom of the integrated circuit die 804. The undercut 821 extends along at least one side of the integrated circuit die 804 and is on the back or bottom side opposite the side containing a number of contact pads 824.

The bonding adhesive 806 can be a thermally and/or electrically conductive or non-conductive adhesive or epoxy that may be line or dot dispensed on the laminate substrate 802 to bond the laminate substrate 802 and the top side 823 in the undercut 821.

The bonding wires 808 can be ground and signal wires connected to the contact pads 824 and to wire bonds 828 on the laminate substrate 802.

The encapsulant 810 covers the laminate substrate 802 and the integrated circuit die 804, and encapsulates the bonding adhesive 806, and the bonding wires 808. In this embodiment, the encapsulant 810 does not cover the back or bottom of the integrated circuit die 804 so that thermal performance can be further improved by allowing air convection or an external heat spreader to access to an underside area 846.

In the present invention, the undercut 821 defines an undercut zone 840 under the integrated circuit die 804 that is the same distance as the distance from the outside edge 820 to the inside edge 822. The distance from the inside edge 822 to the wire bond 828 is designated as a “keep-out zone”, which in this embodiment is a wire bonding keep-out zone 842.

The wire bonding keep-out zone 842 is adjacent to a wire bonding zone 844, which is a region of possible locations for the wire bonds 828. The wire bonding zone 844 is separated by a separation zone 846 from a signal wire bonding zone 848 for containing possible locations for the signal wire bonds 832.

In the past, the wire bonding keep-out zone 842 would have been a specified distance from the outside edge 820 of the integrated circuit die 804. However, in the present invention the distance of the wire bonding keep-out zone 842 is measured from the inside edge 822.

In the present invention, the wire bonding keep-out zone 842 overlaps and is significantly wider than the undercut zone 840. Since the wire bonding keep-out zone 842 is closer to the integrated circuit die 804 than previously possible because of the undercut zone 840, the wire bonding zone 844 may also be closer to the integrated circuit die 804.

The above means that side-by-side dies can be placed closer together than in conventional integrated circuit packages without reducing integrated circuit die size. Conversely, the integrated circuit die size may be increased while maintaining the same wire bonding keep-out zone 842. The integrated circuit die size may be maintained while decreasing the size of the integrated circuit package. At the same time, the present invention will provide shorter wire lengths and higher grounding densities, which result in improved electrical performance over conventional integrated circuit packages.

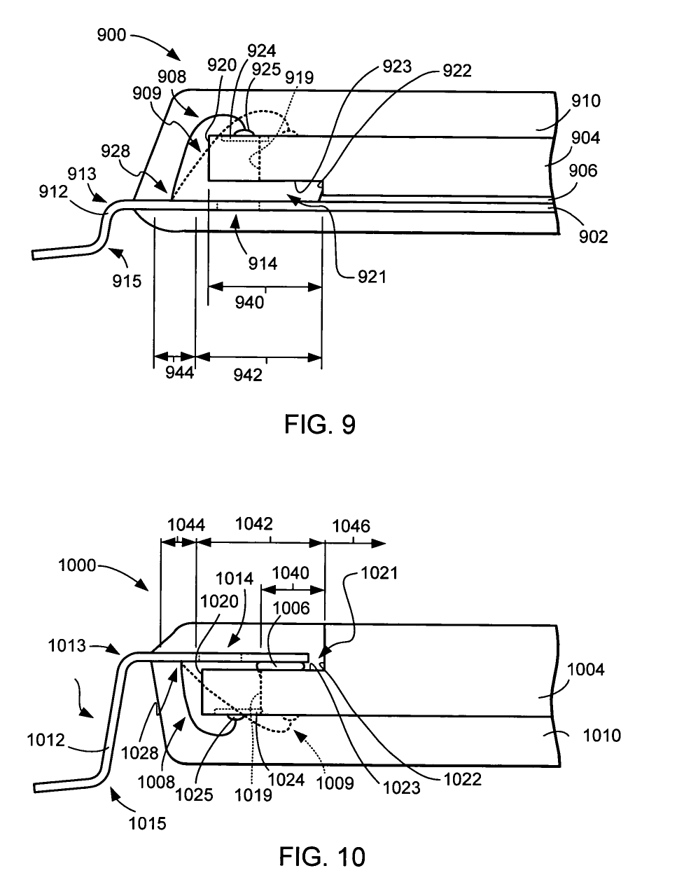

Referring now to FIG. 9, therein is shown a close-up cross-sectional view of a leaded integrated circuit package 900. The leaded integrated circuit package 900 includes a die paddle 902, an integrated circuit die 904, bonding adhesive 906, bonding wires 908, an encapsulant 910, and dedicated lead fingers 912. The dedicated lead fingers 912 are continuous at a horizontal, or angled (not shown), region 914, which is open for other lead fingers. The dedicated lead fingers 912 are connected to the die paddle 902 to provide a dedicated thermal or ground connection.

The die paddle 902 is of a conductive material such as copper or aluminum.

The integrated circuit die 904 has an outside edge 920 (extended from the usual outside edge 919 of the nominal embodiment of the present invention) and an undercut 921 with an inside edge 922, which is a first width from the outside edge 920. The undercut 921 has a top side 923, which is a first height from the bottom of the integrated circuit die 904. The undercut 921 extends along at least one side of the integrated circuit die 904 and is on the back or bottom side opposite the side containing a number of contact pads 924.

The bonding adhesive 906 can be a thermally and/or electrically conductive or non-conductive adhesive or epoxy.

The dedicated lead fingers 912 are connective structures, which extend outward from the integrated circuit die 904 and bend downward at first bend 913s. After extending below the integrated circuit die 904, the dedicated lead fingers 912 bend outward at second bends 915. The die paddle 902 can be directly connected to dedicated lead fingers 912 through tie bars (not shown).

The bonding wires 908 can be ground wires connected by wire bonds 925 to the contact pads 924 and to wire bonds 928 on the dedicated lead fingers 912 between the inner ends of the dedicated lead fingers 912 and the first bends 913. The ground wires are optional but are generally placed on the corners of the integrated circuit die 904 to connect to the corner dedicated lead fingers 912.

The encapsulant 910 encapsulates the package substrate 902, the integrated circuit die 904, the bonding adhesive 906, the bonding wires 908, and portions of the dedicated lead fingers 912.

In the present invention, the undercut 921 defines an undercut zone 940 under the integrated circuit die 904 that is the same distance as the distance from the outside edge 920 to the inside edge 922. The distance from the inside edge 922 to a portion of the dedicated lead fingers 912 are designated as a “keep-out zone”, which in this embodiment is a die-to-finger keep-out zone 942. The die-to-finger keep-out zone 942 is adjacent to a wire bonding zone 944 and is dependent on adhesive 906 resin bleed response only for the dedicated lead fingers 912 directly connected to the die paddle 902 and the wire bonding capability.

In the embodiment shown, the die-to-finger keep-out zone 942 is closer to the integrated circuit die 904 than previously possible because of the undercut zone 940, the wire bonding zone 944 may also be closer to the integrated circuit die 904. This permits increasing the integrated circuit die size while maintaining the same wire bonding keep-out zone or substantially decreasing the package size. At the same time, the present invention will provide shorter wire lengths than in other embodiments as shown by a wire length 909 and higher grounding densities, which result in improved electrical performance over conventional integrated circuit packages.

Referring now to FIG. 10, therein is shown a close-up cross-sectional view of a leaded integrated circuit package 1000. The leaded integrated circuit package 1000 includes an integrated circuit die 1004, bonding adhesive 1006, bonding wires 1008, an encapsulant 1010 and dedicated lead fingers 1012.

The integrated circuit die 1004 has an outside edge 1020 (extended from the usual outside edge 1019 of the nominal embodiment of the present invention) and an undercut 1021 with an inside edge 1022, which is a first width from the outside edge 1020. The undercut 1021 has a top side 1023, which is a first height from the bottom of the integrated circuit die 1004. The undercut 1021 extends along at least one side of the integrated circuit die 1004 and is on the back or bottom side opposite the side containing a number of contact pads 1024.

The bonding adhesive 1006 can be a thermally and/or electrically conductive or non-conductive adhesive or epoxy. In this embodiment, the bonding adhesive 1006, when a thermally conductive adhesive or epoxy, can conduct heat away from the integrated circuit die 1004 through the dedicated lead fingers 1012.

The dedicated lead fingers 1012 are connective structures that are bonded to a flipped over integrated circuit die 1004 to the top side 1023 of the undercut 1021 with the bonding adhesive 1006 on top of the dedicated lead fingers 1012. The dedicated lead fingers 1012 are continuous in a horizontal, or angled (not shown), region 1014, which is open for other lead fingers. The dedicated lead fingers 912 to provide a dedicated thermal or ground connection for the integrated circuit die 1004. The dedicated lead fingers 1012 extend outward from the integrated circuit die 1004 to first bends 1013 where the dedicated lead fingers 1012 bend downward. At second bends 1015, the dedicated lead fingers 1012 bend outward.

The bonding wires 1008 can be ground wires connected by wire bonds 1025 to the contact pads 1024 and to wire bonds 1028 on the top surface of the dedicated lead fingers 1012 before the first bonds 1013.

The encapsulant 1010 encapsulates the integrated circuit die 1004, the bonding adhesive 1006, and the bonding wires 1008. The encapsulant 1010 also encapsulates a short portion of the dedicated lead fingers 1012 before the first bends 1013. In this embodiment, the encapsulant 1010 does not cover the back or bottom of the integrated circuit die 1004 so that thermal performance can be further improved by allowing air convection or an external heat spreader to access to a topside area 1046.

In the present invention, the undercut 1021 defines an undercut zone 1040 under the integrated circuit die 1004 that is the same distance as the distance from the outside edge 1020 to the inside edge 1022. The distance from the inside edge 1022 to a portion of the dedicated lead fingers 1012 are designated as a “keep-out zone”, which in this embodiment is a die-to-finger keep-out zone 1042. The die-to-finger keep-out zone 1042 is adjacent to a wire bonding zone 1044 and is dependent on adhesive 1006 resin bleed response only for the dedicated lead fingers 1012 and the wire bonding capability. The wire bonding keep-out zone 1042 is adjacent to a wire bonding zone 1044.

In the embodiment shown, the wire bonding keep-out zone 1042 overlaps and is wider than the undercut zone 1040. Since the wire bonding keep-out zone 1042 is closer to the integrated circuit die 1004 than previously possible because of the undercut zone 1040, the wire bonding zone 1044 may also be closer to the integrated circuit die 1004. This permits increasing the integrated circuit die size while maintaining the same wire bonding keep-out zone or keeping the integrated circuit die size the same and decreasing the package size. At the same time, the present invention will provide shorter wire lengths than in other embodiments as shown by a wire length 1009 and higher grounding densities, which result in improved electrical performance over convectional integrated circuit packages.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations which fall within the scope of the included claims. All matters set forth herein or shown in the accompanying drawings are to be interpreted in an illustrative and non-limiting sense.

1. An integrated circuit package comprising:
a connective structure having a wire bonding zone and a keep-out zone;
an integrated circuit die having an undercut defining an undercut zone, the keep-out zone overlapping the undercut zone; and
a wire bonded between the integrated circuit die and the connective structure, the wire bonded to the connective structure within the wire bonding zone and outside of the keep-out zone.

2. The integrated circuit package as claimed in claim 1 further comprising wires bonded to the connective structure in a ground wire zone and a signal wire zone, the ground wire zone and the signal wire zone spaced apart around the integrated circuit die.

3. The integrated circuit package as claimed in claim 1 further comprising a further integrated circuit die having a wire bonding region, the wire bonding region adjacent the wire bonding zone.

4. The integrated circuit package as claimed in claim 1 wherein the connective structure includes an insulator, a patterned metal layer on the insulator, and a conductive via through the insulator.

5. The integrated circuit package as claimed in claim 1 further comprising a solder ball on the connective structure, the solder ball in the undercut zone outside of sn inside edge of the integrated circuit die.

6. The integrated circuit package as claimed in claim 1 wherein:
the conductive structure is a lead finger not connected to but extending from the integrated circuit die; and
further comprising:
a package substrate bonded to the integrated circuit die; and
an encapsulant encapsulating the lead finger and holding the lead finger spaced from the integrated circuit die.

7. The integrated circuit package as claimed in claim 1 wherein:
the conductive structure is a lead finger connected to and extending from the undercut of the integrated circuit die.

8. The integrated circuit package as claimed in claim 7 wherein:
the lead finger includes a bend bending an end of the lead finger towards or away from the bottom of the integrated circuit die.

9. The integrated circuit package as claimed in claim 7 wherein:
the lead finger includes a bend bending an end of the lead finger to form a leadless package configuration.

10. The integrated circuit package as claimed in claim 1 wherein:
the conductive structure is a laminate structure extending from the undercut of the integrated circuit die, the laminate structure having a metal pad.

11. An integrated circuit package comprising:
a connective structure having a wire bonding zone and a wire bonding or die-to-finger keep-out zone;
an integrated circuit die having an undercut defining an undercut zone, the wire bonding or die-to-finger keep-out zone overlapping the undercut zone;
a wire bonded between the integrated circuit die and the connective structure, the wire bonded to the connective structure within the wire bonding zone and outside of the wire bonding or die-to-finger keep-out zone; and
an encapsulant over the integrated circuit die and the wire.

12. The integrated circuit package as claimed in claim 11 further comprising wires bonded to the connective structure in a ground wire zone and a signal wire zone, the ground wire zone and the signal wire zone spaced apart around the integrated circuit die, the wires encapsulated in the encapsulant.

13. The integrated circuit package as claimed in claim 11 further comprising:
a further wire;
a further integrated circuit die having a wire bonding region having the further wire bonded therein, the wire bonding region adjacent the wire bonding zone;
the encapsulant encapsulating the integrated circuit, the wire, the further integrated circuit, and the further wire.

14. The integrated circuit package as claimed in claim 11 wherein:
the connective structure includes an insulator, a patterned metal layer on the insulator, and a conductive via through the insulator; and
the encapsulant is over the connective structure.

15. The integrated circuit package as claimed in claim 11 further comprising:
a first solder ball for a signal terminal on the connective structure, the first solder ball in the undercut zone outside of an inside edge of the integrated circuit die; and
a second solder ball for a thermal or ground terminal on the connective structure, the second solder ball inside the inside edge of the integrated circuit die.

16. The integrated circuit package as claimed in claim 11 wherein:
the conductive structure is a lead finger not connected to but extending from the integrated circuit die; and
further comprising:
a package substrate bonded to the integrated circuit die; and
an encapsulant encapsulating the lead finger and holding the lead finger spaced from the integrated circuit die.

17. The integrated circuit package as claimed in claim 11 further including:
a conductive adhesive; and
wherein:
the conductive structure is a lead finger bonded by the conductive adhesive to and extending from the undercut of the integrated circuit die; and
the encapsulant encapsulates a portion of the lead finger and leaves a bottom of the integrated circuit die exposed.

18. The integrated circuit package as claimed in claim 17 wherein:
the lead finger includes a bend outside of the encapsulant bending an end of the lead finger towards or away from the bottom of the integrated circuit die.

19. The integrated circuit package as claimed in claim 17 wherein:
the lead finger includes a bend bending an end of the lead finger to form a leadless package configuration, the end of the lead finger is exposed through the encapsulant.

20. The integrated circuit package as claimed in claim 11 further including:
an adhesive as at least a line, a series of dots, or a combination thereof; and
wherein:
the conductive structure is a laminate structure bonded by the adhesive to and extending from the undercut of the integrated circuit die, the laminate structure having a metal pad; and
the encapsulant encapsulates the laminate structure except for the bottom thereof.
